(19) United States
(12) Patent Application Publication
(10) Pub. No.: US 2026/0255996 A1
(43) Pub. Date: Aug. 27, 2026

(54) WIRING SUBSTRATE

(71) Applicant: IBIDEN CO., LTD., Gifu (JP)

(72) Inventors: Keisuke SHIMIZU, Gifu (JP); Naoki MIZUTANI, Gifu (JP); Yasunobu MIZUNO, Gifu (JP); Shin OISHI, Gifu (JP)

(73) Assignee: IBIDEN CO., LTD., Gifu (JP)

(21) Appl. No.: 19/545,651

(22) Filed: Feb. 20, 2026

(30) Foreign Application Priority Data
Feb. 21, 2025 (JP) 2025-026711

(51) Int. Cl. H10W 70/63; H10W 70/05; H10W 72/20; H10W 90/00

(52) U.S. Cl. CPC H10W 70/635; H10W 70/05; H10W 70/095; H10W 72/20; H10W 90/701; H10W 90/724; H10W 90/734

(57) ABSTRACT

A wiring substrate includes a core part including a glass plate and a through-hole conductor penetrating through the glass plate, and a build-up part formed on a surface of the glass plate of the core part and including conductor layers and insulating layers. The build-up part is formed such that the conductor layers include four or more conductor layers and that the insulating layers include four or more insulating layers, the core part includes a land and an adhesive film formed such that the land is formed on the surface of the glass plate and positioned on the through-hole conductor and that the adhesive film includes a diamond-like carbon film and is covering a surface of the land and the surface of the glass plate not covered by the land.

### CROSS-REFERENCE TO RELATED APPLICATIONS

The present application is based upon and claims the benefit of priority to Japanese Patent Application No. 2025-026711, filed February 21, 2025, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2024-29858 describes a wiring substrate. The entire contents of this publication are incorporated herein by reference.

### SUMMARY OF THE INVENTION

According to one aspect of the present invention, a wiring substrate includes a core part including a glass plate and a through-hole conductor penetrating through the glass plate, and a build-up part formed on a surface of the glass plate of the core part and including conductor layers and insulating layers. The build-up part is formed such that the conductor layers include four or more conductor layers and that the insulating layers include four or more insulating layers, the core part includes a land and an adhesive film formed such that the land is formed on the surface of the glass plate and positioned on the through-hole conductor and that the adhesive film includes a diamond-like carbon film and is covering a surface of the land and the surface of the glass plate not covered by the land.

According to another aspect of the present invention, a wiring substrate includes a core part including a glass plate and a through-hole conductor penetrating through the glass plate, a build-up part formed on a surface of the glass plate of the core part and including conductor layers and insulating layers, and an adhesive film including a diamond-like carbon film and formed between the build-up part and the glass plate such that the adhesive film is formed in contact with the surface of the glass plate. The build-up part is formed such that the conductor layers include four or more conductor layers and that the insulating layers include four or more insulating layers, and the core part is formed such that the through-hole conductor has an end surface formed substantially flush with the surface of the glass plate.

According to yet another aspect of the present invention, a method for manufacturing a wiring substrate includes forming a through-hole conductor in a glass plate such that the through-hole conductor penetrates through the glass plate, forming an adhesive film on the glass plate such that the adhesive film covers a surface of the glass plate, and forming a build-up part on the adhesive film such that the build-up part includes conductor layers and insulating layers. The build-up part is formed such that the conductor layers include four or more conductor layers and that the insulating layers include four or more insulating layers, and the adhesive film includes a diamond-like carbon film.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view illustrating an example of a wiring substrate according to an embodiment of the present invention;

FIG. 1B is a partial enlarged view of the cross-sectional view illustrated in FIG. 1A;

FIG. 1C is a partial enlarged view illustrating a modified example of FIG. 1B;

FIG. 2 is a cross-sectional view illustrating a modified example of a wiring substrate according to an embodiment of the present invention;

FIG. 3A is a cross-sectional view illustrating a method for manufacturing a wiring substrate according to an embodiment of the present invention;

FIG. 3B is a cross-sectional view illustrating a method for manufacturing a wiring substrate according to an embodiment of the present invention;

FIG. 3C is a cross-sectional view illustrating a method for manufacturing a wiring substrate according to an embodiment of the present invention;

FIG. 3D is a cross-sectional view illustrating a method for manufacturing a wiring substrate according to an embodiment of the present invention;

FIG. 3E is a cross-sectional view illustrating a method for manufacturing a wiring substrate according to an embodiment of the present invention;

FIG. 3F is a cross-sectional view illustrating a method for manufacturing a wiring substrate according to an embodiment of the present invention;

FIG. 3G is a cross-sectional view illustrating a method for manufacturing a wiring substrate according to an embodiment of the present invention;

FIG. 3H is a cross-sectional view illustrating a method for manufacturing a wiring substrate according to an embodiment of the present invention;

FIG. 3I is a cross-sectional view illustrating a method for manufacturing a wiring substrate according to an embodiment of the present invention;

FIG. 3J is a cross-sectional view illustrating a method for manufacturing a wiring substrate according to an embodiment of the present invention;

FIG. 3K is a cross-sectional view illustrating a method for manufacturing a wiring substrate according to an embodiment of the present invention;

FIG. 3L is a cross-sectional view illustrating a method for manufacturing a wiring substrate according to an embodiment of the present invention; and

FIG. 3M is a cross-sectional view illustrating a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Wiring Substrate

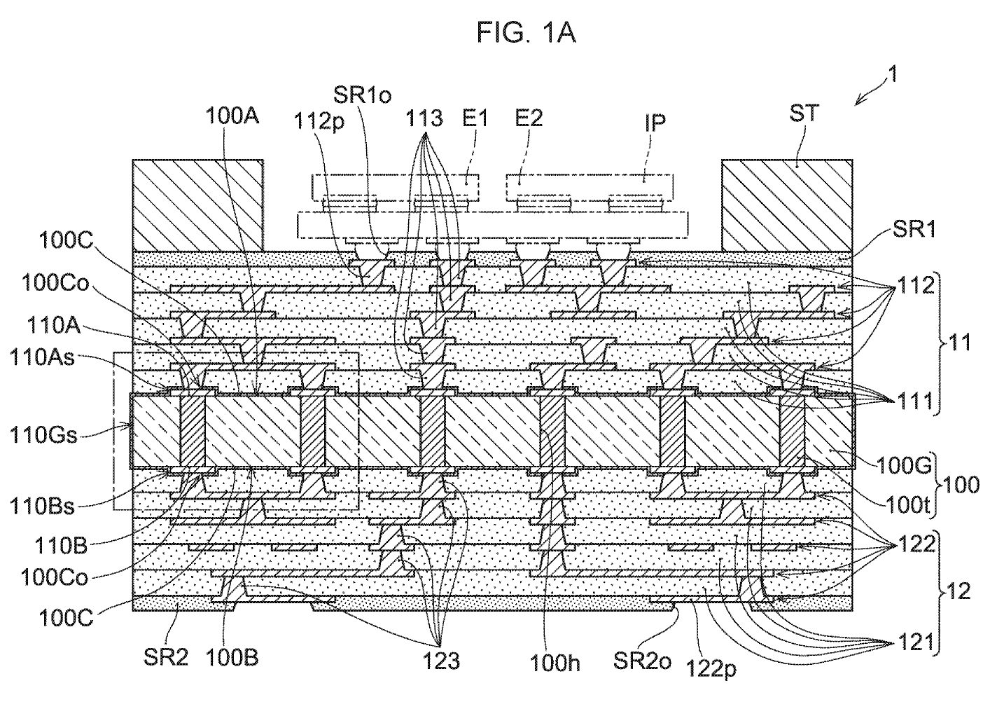

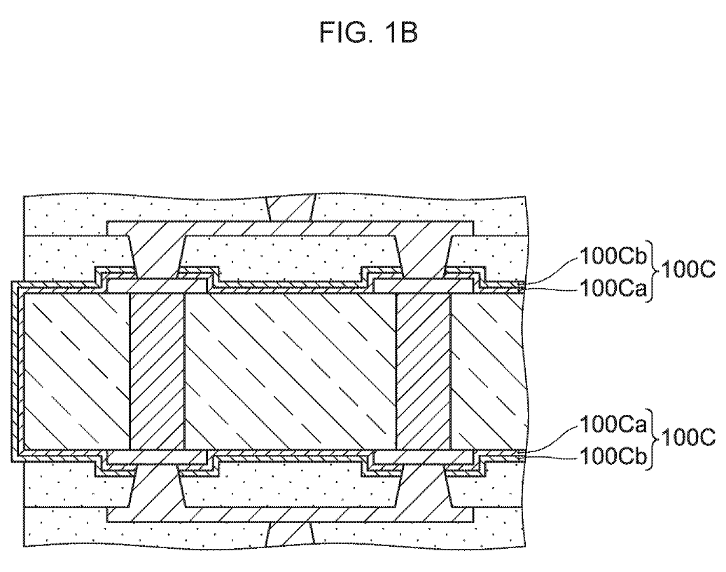

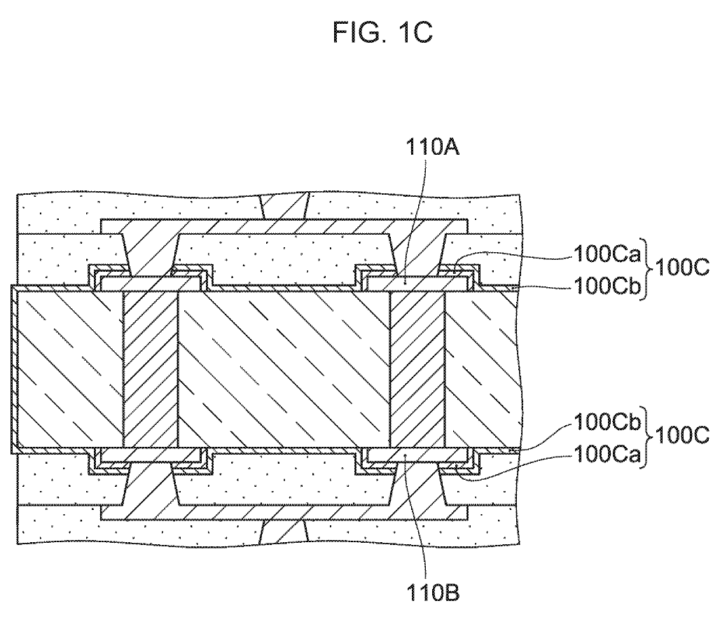

FIG. 1A illustrates a cross-sectional view of a wiring substrate 1, which is an example of a wiring substrate according to an embodiment of the present invention. As illustrated in FIG. 1A, the wiring substrate 1 includes a core part 100 that includes a glass plate (100G) and multiple through-hole conductors (100t) penetrating the glass plate (100G). The glass plate (100G) has a first surface (100A) and a second surface (100B) on an opposite side with respect to the first surface (100A). The through-hole conductors (100t) are mainly formed of a conductive material that fills through holes (100h) penetrating the glass plate (100G). The core part 100 includes metal wiring layers (110A, 110B) that are respectively provided on the first surface (100A) and the second surface (100B) of the glass plate (100G). The metal wiring layers (110A, 110B) correspond to lands of the through-hole conductors (100t).

A wiring substrate according to an embodiment of the present invention includes a build-up part formed of four or more conductor layers and four or more insulating layers on both sides or on one side of the glass plate (100G). In the wiring substrate 1 illustrated in FIG. 1A, a first build-up part 11 is formed on the first surface (100A) side of the glass plate (100G), and a second build-up part 12 is formed on the second surface (100B) side. In the following description, the wiring substrate 1 including both the first build-up part 11 and the second build-up part 12 is described; however, a wiring substrate according to an embodiment of the present invention does not necessarily include both build-up parts and may include only one of the build-up parts.

In the description of the wiring substrate, a side farther from the core part 100 is also referred to as “upper,” “upper side,” “side,” or “outer side,” and a side closer to the core part 100 is also referred to as “lower,” “lower side,” “inner,” or “inner side.” For the insulating layers and the conductor layers, a surface facing away from the core part 100 is also referred to as an “upper surface,” and a surface facing the core part 100 side is also referred to as a “lower surface.” The term “in plan view” means viewing an object along a thickness direction of the wiring substrate 1 (that is, a thickness direction of the glass plate (100G)). A surface facing a direction perpendicular to the thickness direction of the wiring substrate 1 is also referred to as a “side surface.”

In the wiring substrate 1, the first build-up part 11 includes five sets of insulating layers 111 and conductor layers 112 laminated on the first surface (100A) side of the glass plate (100G). The insulating layers and the conductor layers of the five sets of insulating layers 111 and conductor layers 112 are alternately laminated. The second build-up part 12 includes five sets of insulating layers 121 and conductor layers 122 laminated on the second surface (100B) side of the glass plate (100G). The insulating layers and the conductor layers of the five sets of insulating layers 121 and conductor layers 122 are alternately laminated.

The first surface (100A) and the second surface (100B) of the glass plate (100G), as well as the upper surfaces of the metal wiring layers (110A, 110B), are preferably non-roughened surfaces. Further, side surfaces (110As) of the metal wiring layer (110A), side surfaces (110Bs) of the metal wiring layer (110B), and side surfaces (100Gs) of the glass plate (100G) can be non-roughened surfaces.

A region of the first surface (100A) of the glass plate (100G) exposed from the metal wiring layer (110A), and the upper surface of the metal wiring layer (110A), as well as a region of the second surface (100B) of the glass plate (100G) exposed from the metal wiring layer (110B), and the upper surface of the metal wiring layer (110B), are covered by an adhesive film (100C) except for regions below openings (100Co). Further, preferably, the side surfaces (110As) of the metal wiring layer (110A), the side surfaces (110Bs) of the metal wiring layer (110B), and the side surfaces (100Gs) of the glass plate (100G) are covered by the adhesive film (100C). The adhesive film (100C) is preferably a physical vapor deposition film such as a sputtering film or a vacuum deposition film, or a chemical vapor deposition film such as a CVD film. The adhesive film (100C) has a thickness of, for example, 10nm or more and 10μm or less. As described above, when a wiring substrate according to an embodiment of the present invention includes only one of the first build-up part 11 and the second build-up part 12, the adhesive film (100C) may be formed on the upper surface of either the metal wiring layer (110A) or the metal wiring layer (110B), and on either the first surface (100A) or the second surface (100B) of the glass plate (100G).

The adhesive film (100C) includes a diamond-like carbon (DLC) film. The diamond-like carbon film is preferably a film formed by plasma CVD using C₇H₈ gas. Diamond-like carbon has good adhesion to silicon (Si), thereby allowing the core part 100 to firmly adhere to the insulating layer 111 that constitutes the lowermost layer of the first build-up part 11 formed on the first surface (100A) side of the glass plate (100G). Further, the core part 100 firmly adheres to the insulating layer 121 that constitutes the lowermost layer of the second build-up part 12 formed on the second surface (100B) side of the glass plate (100G). Therefore, the build-up parts that are respectively formed on the two surfaces of the core part 100 are unlikely to peel off.

FIG. 1B is an enlarged view of a region (I) in FIG. 1A. Although the adhesive film (100C) has a single-layer structure in FIG. 1A, as illustrated in FIG. 1B, it may have a laminated structure. When the adhesive film (100C) has a laminated structure, it can preferably be a laminated film of two or more layers including a diamond-like carbon film and a silicon intermediate film. The silicon intermediate film is provided particularly to further promote adhesion between the diamond-like carbon film and the metal wiring layer (conductor layer). The silicon intermediate film is formed by CVD using a silicon-based gas, and after that, the diamond-like carbon film is continuously formed by CVD using a different gas.

When the adhesive film (100C) is a two-layer laminated film as illustrated in FIG. 1B, a diamond-like carbon film as a first adhesive film (100Cb) may be formed on the region of the first surface (100A) of the glass plate (100G) exposed from the metal wiring layer (110A), the upper surface of the metal wiring layer (110A), the region of the second surface (100B) of the glass plate (100G) exposed from the metal wiring layer (110B), and the upper surface of the metal wiring layer (110B); and a silicon intermediate film as a second adhesive film (100Ca) may be formed between the first adhesive film (100Cb) and the glass plate (100G). Alternatively, a silicon intermediate film may be formed as the first adhesive film (100Cb), and a diamond-like carbon film may be formed as the second adhesive film (100Ca).

The adhesive film (100C) may also be a three-layer laminated film. For example, a first silicon intermediate film may be formed on the region of the first surface (100A) of the glass plate (100G) exposed from the metal wiring layer (110A), the upper surface of the metal wiring layer (110A), the region of the second surface (100B) of the glass plate (100G) exposed from the metal wiring layer (110B), and the upper surface of the metal wiring layer (110B); a diamond-like carbon film may be formed on the upper surface of the first silicon intermediate film; and further, a second silicon intermediate film may be formed on the upper surface of the diamond-like carbon film.

Further, as illustrated in FIG. 1C, the second adhesive film (100Ca) is provided between the first adhesive film (100Cb) and the metal wiring layers (110A, 110B) in order to improve adhesion between the first adhesive film (100Cb) and the metal wiring layers (110A, 110B), and the second adhesive film (100Ca) may be patterned along the shape of the metal wiring layers (110A, 110B). In this case, in the region of the first surface (100A) of the glass plate (100G) exposed from the metal wiring layer (110A) and the region of the second surface (100B) of the glass plate (100G) exposed from the metal wiring layer (110B), the first surface (100A) and the second surface (100B) are in direct contact with the first adhesive film (100Cb) without the second adhesive film (100Ca) interposed therebetween.

As described above, due to the adhesive film (100C) of the laminated structure, the adhesion between the core part 100 and the insulating layers (111, 121) is further enhances and the build-up parts that are respectively formed on the two surfaces of the core part 100 become even less likely to peel off.

The adhesive film (100C) may also be formed on the upper surfaces of each insulating layer and each conductor layer of the five sets of insulating layers 111 and conductor layers 112 of the first build-up part 11. As a result, the insulating layers and the conductor layers of the first build-up part 11 are firmly adhered to each other, and delamination is less likely to occur. The adhesive film (100C) may also be formed on the upper surfaces of each insulating layer and each conductor layer of the five sets of insulating layers 121 and conductor layers 112 of the second build-up part 12. As a result, the insulating layers and the conductor layers of the second build-up part 12 are firmly adhered to each other, and delamination is less likely to occur.

Each insulating layer 111 of the first build-up part 11 includes via conductors 113 that connect conductor layers (conductor layers 112, or a conductor layer 112 and the metal wiring layer (110A)) formed on both sides (upper side and lower side) in a thickness direction of the insulating layer 111. Each insulating layer 121 of the second build-up part 12 includes via conductors 123 that connect conductor layers (conductor layers 122, or a conductor layer 122 and the metal wiring layer (110B)) formed on both sides in a thickness direction of the insulating layer 121.

In FIG. 1A, each of the through holes (100h) is illustrated as having substantially the same inner diameter throughout the entire thickness direction of the glass plate (100G). Each of the through holes (100h) may have a shape that is reduced in diameter toward a central portion in the thickness direction of the glass plate (100G) from both the first surface (100A) side and the second surface (100B) side. For convenience, the term “reduced in diameter” is used. However, the shape of each of the through holes (100h) and through-hole conductors (100t)) in plan view is not necessarily limited to a circular shape. The term “diameter” refers to a linear distance between two most distant points on an outer edge of an object in plan view, and the term “reduced in diameter” means that the linear distance becomes smaller.

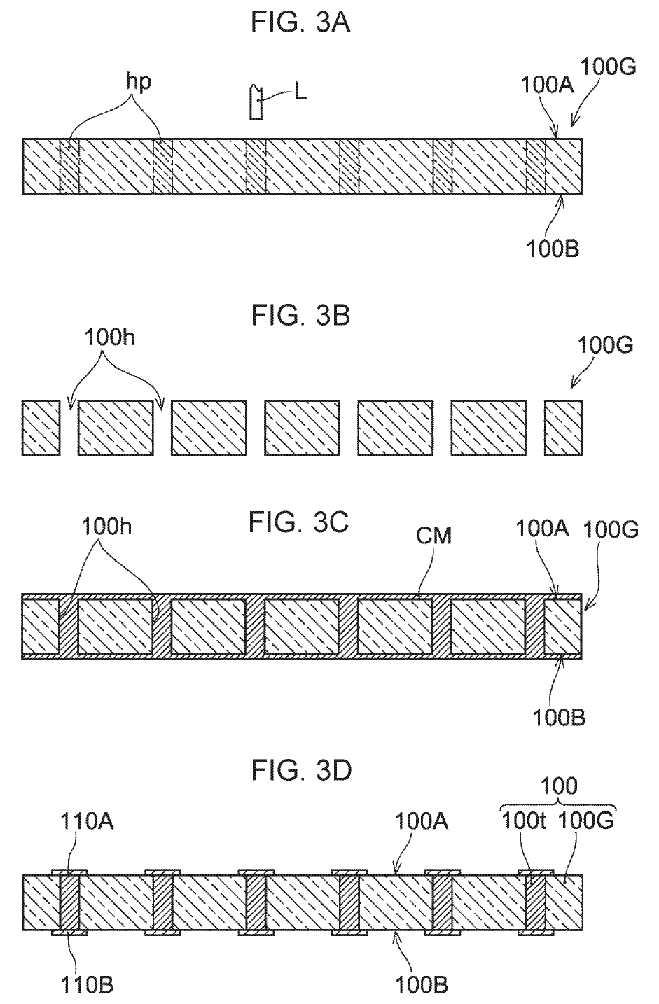

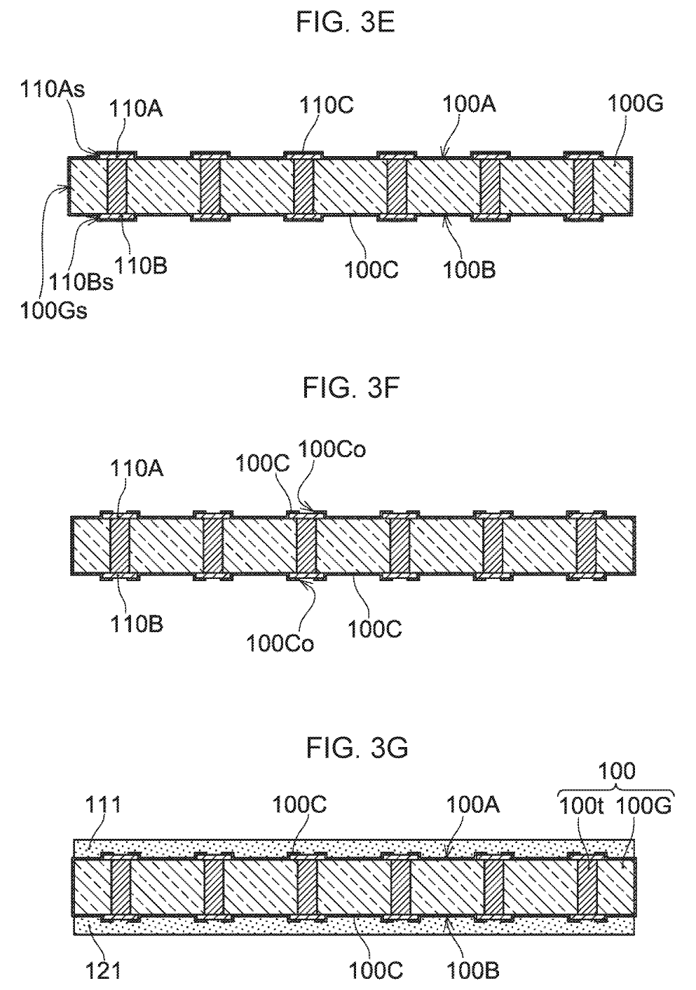

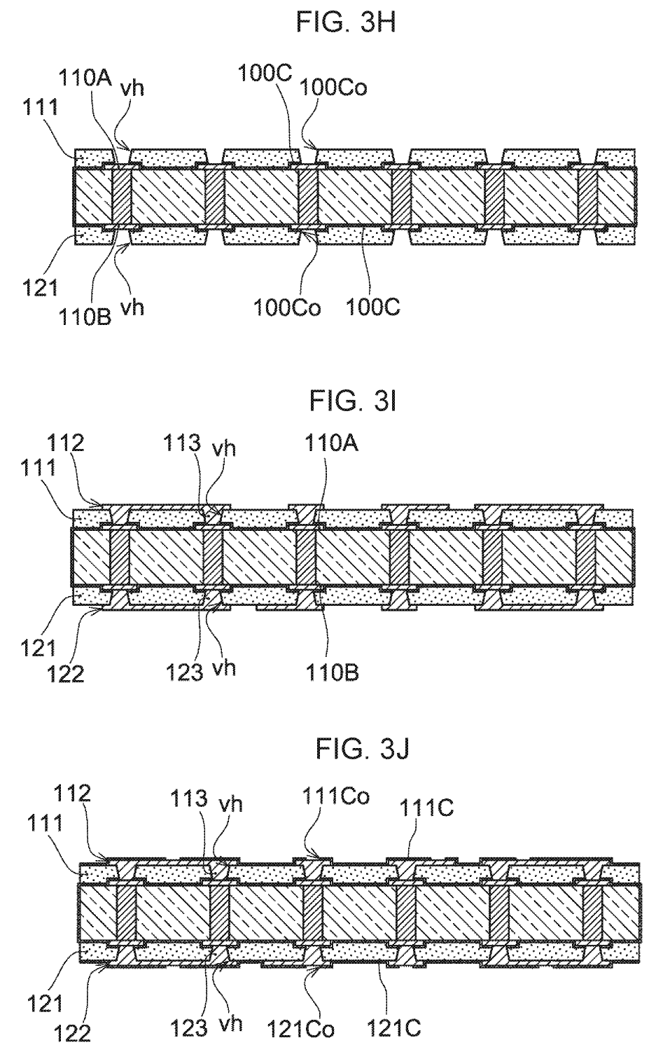

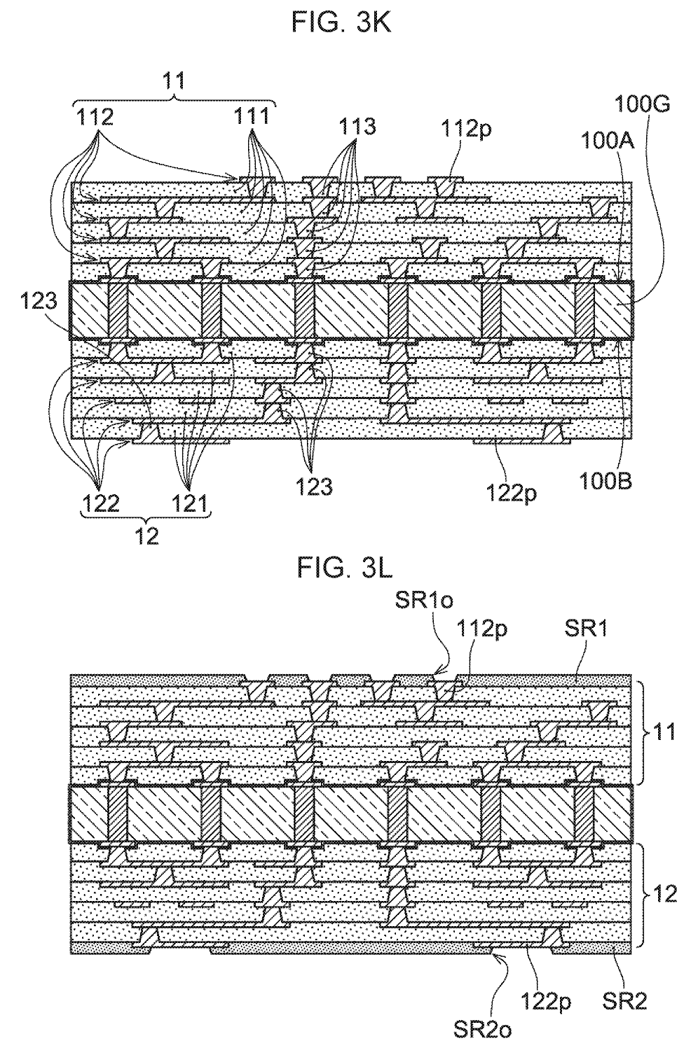

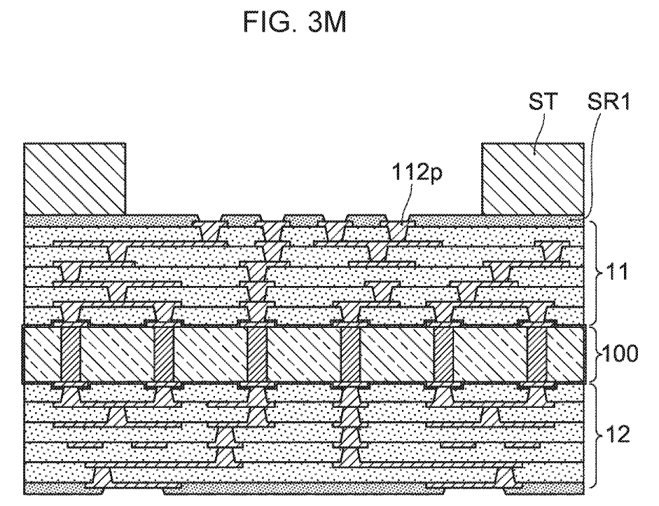

The through-hole conductors (100t) are formed of a conductive material that entirely fills the through holes (100h). As illustrated in FIG. 3C to be described later, the entire through-hole conductors (100t) are formed of, for example, a conductive material such as copper. Both end surfaces of each of the through-hole conductors (100t) are respectively positioned substantially flush with the first surface (100A) and the second surface (100B) of the glass plate (100G) and are respectively connected to the metal wiring layers (110A, 110B). The through-hole conductors (100t) connect the conductor layers 112 of the first build-up part 11 and the conductor layers 122 of the second build-up part 12 via the metal wiring layer (110A) and the via conductors 113, as well as via the metal wiring layer (110B) and the via conductors 123.

A solder resist layer (SR1) is formed on the first build-up part 11. A solder resist layer (SR2) is formed on the second build-up part 12. Openings (SR1o) are formed in the solder resist layer (SR1), and conductor pads (112p) of the outermost conductor layer 112 in the first build-up part 11 are exposed from the openings (SR1o). Openings (SR2o) are formed in the solder resist layer (SR2), and conductor pads (122p) of the outermost conductor layer 122 in the second build-up part 12 are exposed from the openings (SR2o).

The conductor pads (112p) can be connection pads used for mounting an external electronic component or the like. As illustrated, the conductor pads (112p) can be electrically and mechanically connected by a bonding material such as solder to connection pads of an external member (IP), which can be, for example, a silicon interposer. In the example illustrated in FIG. 1A, for example, components (E1, E2), which can be electronic components such as semiconductor integrated circuit devices or transistors (for example, logic chips or memory elements), are connected on the member (IP). That is, electronic components primarily mounted on an interposer may be mounted on the wiring substrate 1. On the other hand, the conductor pads (122p) may be used, for example, for connection to any substrate (such as an external motherboard), an electrical component, or a mechanical component (not illustrated).

In the example illustrated in FIG. 1A, a reinforcing material (ST) is provided on the solder resist layer (SR1). The reinforcing material (ST) is provided so as to surround a region where the external member (IP) is mounted while avoiding a region where the conductor pads (112p) are provided, so as not to hinder the mounting of the components on the surface of the wiring substrate 1. It is thought that by providing the reinforcing material (ST), deformation such as warpage or bending of the wiring substrate 1 is suppressed. It is thought that by suppressing deformation of the wiring substrate 1, the components (E1, E2) can be stably mounted on the wiring substrate 1 and good connection reliability can be ensured.

The glass substrate (100G) constituting the core part 100 is formed of glass selected from soda-lime glass, aluminosilicate glass, borosilicate glass, fluoro glass, chalcogenide glass, alkali-free glass, and quartz glass. Alternatively, it may be formed of an organic glass such as acrylic glass. The glass plate (100G) may contain, as additives, magnesium, calcium, manganese, aluminum, lead, iron, chromium, potassium, sulfur, antimony, boron, or the like. For example, since a glass material such as soda-lime glass exhibits superior rigidity compared to epoxy resin or the like, it is thought that significant warpage is less likely to occur in the wiring substrate 1. Further, considering adhesiveness to diamond-like carbon, the higher the concentration of silicon contained in the glass plate (100G), the more preferable it is.

The insulating layers 111 constituting the first build-up part 11 and the insulating layers 121 constituting the second build-up part 12 are formed using, for example, an insulating resin such as epoxy resin, bismaleimide triazine resin (BT resin), or phenol resin. The insulating layers (111, 121) may each contain a reinforcing material (core material) such as glass fiber and/or an inorganic filler such as silica or alumina.

The solder resist layers (SR1, SR2) are formed using, for example, a photosensitive epoxy resin, polyimide resin, or the like. The reinforcing material (ST) is formed of any material capable of suppressing deformation of the wiring substrate 1. For example, any metal material such as a copper alloy, an aluminum alloy, or an iron alloy may be used as a material for the reinforcing material (ST), and as an example, stainless steel having high rigidity is used.

The conductor layers (112, 122), the via conductors (113, 123), the metal wiring layers (110A, 110B), and the through-hole conductors (100t) can be formed using any metal such as copper or nickel. For example, the metal wiring layers (110A, 110B) can be a metal foil such as copper foil and/or a metal film formed by plating, sputtering, or the like. The conductor layers (112, 122), the via conductors (113, 123), the metal wiring layers (110A, 110B), and the through-hole conductors (100t) are illustrated in FIG. 1A in a simplified manner as each having a single-layer structure for ease of viewing, but can each have a laminated structure of two or more layers. The conductor layers (112, 122), the via conductors (113, 123), the metal wiring layers (110A, 110B), and the through-hole conductors (100t) can each have a two-layer structure including a metal film layer (for example, an electroless copper plating film) and a plating film layer (for example, an electrolytic copper plating film). The conductor layers (112, 122) and the metal wiring layers (110A, 110B) included in the wiring substrate 1 are each patterned so as to have predetermined conductor patterns.

### Modified Example

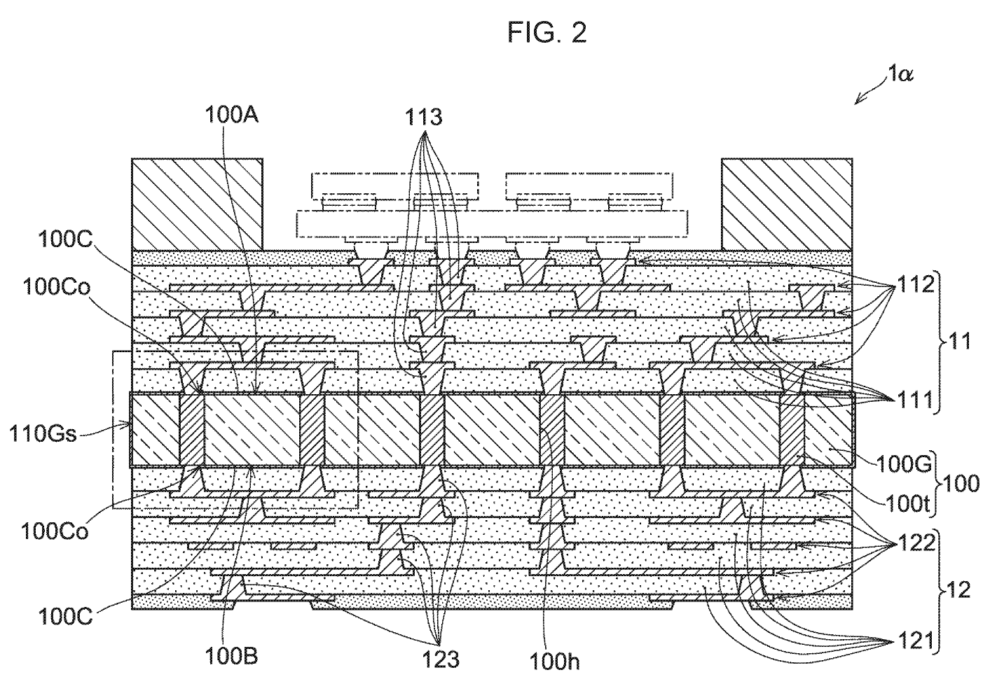

FIG. 2 illustrates a cross-sectional view of a wiring substrate (1α), which is a modified example of the wiring substrate 1. As illustrated in FIG. 2, the wiring substrate (1α) differs from the wiring substrate 1 in that it does not include the metal wiring layers (110A, 110B) (see FIG. 1) corresponding to lands of the through-hole conductors (100t), that is, it has a so-called landless structure, and since the other structural elements are the same as those of the wiring substrate 1, descriptions thereof can be omitted.

The first surface (100A) and the second surface (100B) of the glass plate (100G) are preferably non-roughened surfaces. Both end surfaces of each of the through-hole conductors (100t) penetrating the glass plate (100G) are exposed so as to be, respectively positioned substantially flush with the first surface (100A) and the second surface (100B) of the glass plate (100G).

The first surface (100A) and the second surface (100B) of the glass plate (100G) are covered by the adhesive film (100C). The adhesive film (100C) has openings (100Co) above the end surfaces of the through-hole conductors (100t), each opening being smaller than the end surface of each of the through-hole conductors (100t), and the end surfaces of the through-hole conductors (100t) are exposed in the openings (100Co). In other words, the adhesive film (100C) is formed so as to be in contact with a portion of the periphery of each end surface of the through-hole conductors (100t).

The first build-up part 11 is formed on the first surface (100A) side of the glass plate (100G). The lowermost insulating layer 111 of the first build-up part 11 is laminated on the upper surface of the adhesive film (100C) on the first surface (100A) side of the glass plate (100G). A bottom surface of each via conductor 113 included in the insulating layer 111 is connected to one end surface of a through-hole conductor (100t) exposed in an opening (100Co) of the adhesive film (100C).

The second build-up part 12 is formed on the second surface (100B) side of the glass plate (100G). The lowermost insulating layer 121 of the second build-up part 12 is laminated on the upper surface of the adhesive film (100C) on the second surface (100B) side of the glass plate (100G). A bottom surface of a via conductor 123 included in the insulating layer 121 is connected to the other end surface of a through-hole conductor (100t) exposed in an opening (100Co) of the adhesive film (100C).

### Method for Manufacturing Wiring Substrate

A method for manufacturing a wiring substrate according to an embodiment of the present invention is described with reference to the drawings. FIGS. 3A to 3M illustrate a method for manufacturing a wiring substrate according to an embodiment of the present invention, using the wiring substrate 1 illustrated in FIG. 1A as an example. Unless there is a description different from the description regarding the structures and materials of the structural elements of the wiring substrate 1 in FIG. 1A, the structural elements can be formed using any of the structures and materials described with reference to FIG. 1A with respect to the structural elements. In a method for manufacturing a wiring substrate according to an embodiment of the present invention, a build-up part constituted by four or more conductor layers and four or more insulating layers is formed on both surfaces or one

surface of the glass plate (100G). In the following, a method for manufacturing the wiring substrate 1 including both the first build-up part 11 and the second build-up part 12 is described; however, in a method for manufacturing a wiring substrate according to an embodiment of the present invention, it does not necessarily have to form both build-up parts, but it is also possible that only one of the two build-up parts is formed.

As illustrated in FIG. 3A, the glass plate (100G) having the first surface (100A) and the second surface (100B) is prepared. The first surface (100A) and the second surface (100B) of the glass plate (100G) are preferably not subjected to a roughening treatment. Further, the side surfaces (100Gs) of the glass plate (100G) are not subjected to a roughening treatment.

Next, laser light (L) is irradiated onto positions on the glass plate (100G) where the through holes (100h) (see FIG. 3B) are to be formed in plan view. As the laser light (L) passes through the glass plate (100G), the glass structure in a region through which the laser light (L) has passed is altered, thereby forming a modified portion (hp). That is, the glass structure in the region through which the laser light (L) has passed is altered so as to be more highly reactive to an etching solution used in the process of FIG. 3B described later, compared to the glass structure in a region through which the laser light (L) has not passed. Each modified portion (hp) is formed along the thickness direction of the glass plate (100G) so as to extend from one to the other of the first surface (100A) and the second surface (100B) of the glass plate (100G). In the example of FIG. 3A, each modified portion (hp) is formed in a columnar shape having a substantially constant diameter in the thickness direction; however, the shape of each modified portion (hp) is not limited to this. Each modified portion (hp) may be formed in a shape that is reduced in diameter toward a central portion in the thickness of the glass plate (100G) from both the first surface (100A) side and the second surface (100B) side. The modified portions (hp) are removed faster than surrounding unmodified portions in a subsequent etching process. That is, the through holes (100h) can be formed.

As the laser light (L), a helium-neon laser, an argon ion laser, an excimer laser, various YAG lasers, and the like are used. For ease of formation of the modified portions (hp) and for avoiding excessive stress on the glass plate (100G), laser light (L) having a wavelength of about 350nm or more and 3000nm or less is preferably used. An output of the laser light (L) is appropriately adjusted so that the modified portions (hp) can be formed as intended. The laser light (L) may be irradiated continuously or in pulses.

Next, the modified portions (hp) formed by irradiation of the laser light (L) are removed, for example, using an etching solution. Specifically, the modified portions (hp) are removed by immersing the glass plate (100G), in which the modified portions (hp) have been formed, in an etching solution containing, for example, an aqueous hydrofluoric acid solution. The concentration of the aqueous hydrofluoric acid solution is appropriately adjusted so that etching proceeds sufficiently. Further, from a point of view of promoting etching, the etching solution may contain hydrochloric acid and/or nitric acid, and ultrasonic waves may be propagated to an etching tank.

By removing the modified portions (hp) illustrated in FIG. 3A, as illustrated in FIG. 3B, the multiple cylindrical through holes (100h) penetrating the glass plate (100G) are formed. Through holes (100h) having any planar shape such as a circular shape are formed.

Next, as illustrated in FIG. 3C, the surfaces of the glass plate (100G) are covered with a conductive material (CM), and the through holes (100h) are filled with the conductive material (CM). The conductive material (CM) can be formed using any metal such as copper or nickel. The conductive material (CM) is illustrated in FIG. 3C in a simplified manner as having a single-layer structure for ease of viewing, but can be formed to have a laminated structure of two or more layers. The conductive material (CM) can be formed to have a two-layer structure including a metal film layer and a plating film layer. For example, a seed metal film layer is formed over the entire surfaces of the glass plate (100G) and entire inner wall surfaces of the through holes (100h) by electroless plating or sputtering. Further, an electrolytic plating film layer is formed by electrolytic plating using the formed seed metal film layer as a power feeding layer. As a result, the conductive material (CM) having a two-layer structure including the seed metal film layer and the electrolytic plating film layer is formed. The conductive material (CM) filled in the through holes (100h) constitutes the through-hole conductors (100t) (see FIG. 3D) that penetrate the glass plate (100G) in the thickness direction, and the conductive material (CM) covering the first surface (100A) and the second surface (100B) of the glass plate (100G) is formed into the metal wiring layers (110A, 110B) (see FIG. 3D) by processing described later using FIG. 3D.

The through-hole conductors (100t) are formed in a shape similar to the shape of the modified portions (hp) illustrated in FIG. 3A. One end surface of each through-hole conductor (100t) is positioned substantially flush with the first surface (100A) and connected to the metal wiring layer (110A), and the other end surface of the through-hole conductor (100t) is positioned substantially flush with the second surface (100B) and connected to the metal wiring layer (110B).

Next, as illustrated in FIG. 3D, the metal wiring layers (110A, 110B) are formed. The metal wiring layers (110A, 110B) are formed, for example, using a subtractive method. In the subtractive method, a photoresist (not illustrated) is applied to the surface of the conductive material (CM), a mask printed with desired patterns is positioned on the photoresist, and then ultraviolet light is irradiated. Unexposed portions of the photoresist are removed using a predetermined chemical solution, and the conductive material (CM) is exposed. The exposed conductive material (CM) is removed by etching, and then, the remaining photoresist is removed. The conductive material (CM) remaining in this manner constitutes the metal wiring layers (110A, 110B) as illustrated in FIG. 3D. Through the above processes, the formation of the core part 100 constituted by the glass plate (100G) including the through-hole conductors (100t) is completed.

Next, as illustrated in FIG. 3E, the adhesive film (100C) is laminated on the region of the first surface (100A) of the glass plate (100G) exposed from the metal wiring layer (110A), and the upper surface of the metal wiring layer (110A), as well as the region of the second surface (100B) of the glass plate (100G) exposed from the metal wiring layer (110B), and the upper surface of the metal wiring layer (110B). Further, preferably, the adhesive film (100C) may also be laminated on the side surfaces (110As) of the metal wiring layer (110A), the side surfaces (110Bs) of the metal wiring layer (110B), and the side surfaces (100Gs) of the glass plate (100G).

The first surface (100A) and the second surface (100B) of the glass plate (100G), as well as the upper surfaces of the metal wiring layers (110A, 110B), are preferably not subjected to a roughening treatment. Further, the side surfaces (110As) of the metal wiring layer (110A), the side surfaces (110Bs) of the metal wiring layer (110B), and the side surfaces (100Gs) of the glass plate (100G) are not subjected to a roughening treatment. Further, as described above, in the case where only one of the first build-up part 11 and the second build-up part 12 is formed in a wiring substrate according to an embodiment of the present invention, the adhesive film (100C) may be formed on the upper surface of either the metal wiring layer (110A) or the metal wiring layer (110B), and on either the first surface (100A) or the second surface (100B) of the glass plate (100G). However, although the number of manufacturing processes increases, in order to further enhance adhesion, a roughening treatment may be applied to the first surface (100A) and the second surface (100B) of the glass plate (100G), as well as to the metal wiring layers (110A, 110B).

The adhesive film (100C) may be formed to have a single-layer structure of a diamond-like carbon film, or to have a laminated structure including a diamond-like carbon film as illustrated in FIGS. 1B and 1C. The diamond-like carbon film illustrated in FIGS. 1B and 1C has a thickness of, for example, 10nm or more and 10μm or less. As a result, the adhesion between the insulating layers (111, 121) formed on the upper surface of the adhesive film (100C) in the process of FIG. 3G described later and the core part 100 is improved, and the build-up parts that are respectively formed on the two surfaces of the core part 100 become less likely to peel off.

Next, as illustrated in FIG. 3F, the openings (100Co) are formed in the adhesive film (100C). The openings (100Co) are respectively formed at formation sites of the via conductors (113, 123) above the metal wiring layers (110A, 110B) in order to electrically connect the via conductors (113, 123) formed in the process of FIG. 3I described later with the metal wiring layers (110A, 110B). To form the openings (100Co), a mask (not illustrated) having openings corresponding to formation sites of the openings (100Co) is formed on the adhesive film (100C). After that, the adhesive film (100C) exposed in the openings of the mask is removed by a dry etching process such as reactive ion etching, thereby forming the openings (100Co). The mask is removed after completion of the dry etching. The openings (100Co) may also be formed by laser processing. As a result, the upper surfaces of the metal wiring layers (110A, 110B) are exposed at bottom surfaces of the openings (100Co).

The formation of the openings (100Co) in the adhesive film (100C) may be performed simultaneously with formation of through holes (vh) described later with reference to FIG. 3H. In this case, the process described above using FIG. 3F can be omitted.

Next, as illustrated in FIG. 3G, an insulating layer 111 is formed on the upper surface of the adhesive film (100C) on the first surface (100A) side of the glass plate (100G), and an insulating layer 121 is formed on the upper surface of the adhesive film (100C) on the second surface (100B) side. The insulating layers (111, 121) are formed by laminating and thermocompression bonding resin films formed of epoxy resin or the like on the two surfaces of the core part 100. As illustrated in FIG. 3F, since the adhesive film (100C) is formed on the first surface (100A) and the second surface (100B) of the glass plate (100G), as well as on the upper surfaces of the metal wiring layers (110A, 110B), the adhesion of the insulating layers (111, 121) to the glass plate (100G) and the metal wiring layers (110A, 110B) can be enhanced.

Next, as illustrated in FIG. 3H, the through holes (vh) are formed in the insulating layer 111 and the insulating layer 121 at formation positions of the via conductors (113, 123) (see FIG. 3I), for example, by irradiation with CO₂ laser light. The openings (100Co) are formed in the adhesive film (100C) at the formation sites of the via conductors (113, 123). That is, the through holes (vh) are formed so as to overlap with the openings (100Co) of the adhesive film (100C) in plain view. Therefore, the upper surfaces of the metal wiring layers (110A, 110B) are exposed at bottom surfaces of the through holes (vh) via the openings (100Co) of the adhesive film (100C).

As described above, in the case where the process of forming the openings (100Co) in the adhesive film (100C) described using FIG. 3F is omitted, the openings (100Co) in the adhesive film (100C) can be formed simultaneously with the formation of the through holes (vh) in the process of forming the through holes (vh) in the insulating layer 111 and the insulating layer 121 illustrated in FIG. 3H.

Next, as illustrated in FIG. 3I, a conductor layer 112 is formed on the insulating layer 111, and a conductor layer 122 is formed on the insulating layer 121. The via conductors 113 are formed in the through holes (vh) of the insulating layer 111, and the via conductors 123 are formed in the through holes (vh) of the insulating layer 121. The via conductors 113 are formed so as to be in contact with the upper surface of the metal wiring layer (110A) exposed via the openings (100Co) at the bottom surfaces of the through holes (vh) in the insulating layer 111. The via conductors 123 are formed so as to be in contact with the upper surface of the metal wiring layer (110B) exposed via the openings (100Co) at the bottom surfaces of the through holes (vh) in the insulating layer 121.

The conductor layers (112, 122) are formed using any metal film formation method and can have a single-layer structure or a laminated structure combining different metal film formation methods. When the conductor layers (112, 122) have a laminated structure, each layer may be formed of a different conductor material. The conductor layers (112, 122) can be formed, for example, using a semi-additive method.

In the semi-additive method, first, a seed layer (not illustrated) is formed using a sputtering method or an electroless plating method on the upper surfaces of the metal wiring layers (110A, 110B) exposed at the bottoms of the through holes (vh), on the side wall surfaces of the through holes (vh), and on the surfaces of the insulating layer 111 and the insulating layer 121. Further, a resist layer (not illustrated) having openings corresponding to the conductor layer 112 and the conductor layer 122 is formed on the seed layer. Then, an electrolytic plating film layer (not illustrated) is formed in the openings of the resist layer using an electrolytic plating method using the seed layer as a power feeding layer. As a result, the via conductors 113 and the via conductors 123 are formed in the through holes (vh). After the resist layer is removed, using the electrolytic plating film layer as a mask, a portion of the seed layer not covered by the plating layer is removed by etching, and the conductor layer 112 and the conductor layer 122 including the conductor patterns are respectively formed on the insulating layer 111 and the insulating layer 121.

Preferably, as illustrated in FIG. 3J, an adhesive film (111C) may be formed on the upper surface of the conductor layer 112 and on the upper surface of the insulating layer 111 exposed from the conductor layer 112. An adhesive film (121C) may be formed on the upper surface of the conductor layer 122 and on the upper surface of the insulating layer 121 exposed from the conductor layer 122. In the adhesive films (111C, 121C), similar to the adhesive film (100C) illustrated in FIG. 3F, openings (111Co, 121Co) are formed at formation sites of the via conductors (113, 123) to be formed on the upper surfaces of the adhesive films (111C, 121C). The adhesive films (111C, 121C) and the openings (111Co, 121Co) can be formed using methods and materials similar to those of the adhesive film (100C) and the openings (100Co) illustrated in FIGS. 3E and 3F. As a result, the adhesion of the insulating layers and the conductor layers constituting the first build-up part 11 and the second build-up part 12 is enhanced, and delamination becomes less likely to occur.

Next, as illustrated in FIG. 3K, on the first surface (100A) side of the glass plate (100G), four more sets of insulating layers 111 and conductor layers 112 are formed using methods similar to the methods for forming the insulating layer 111 and the conductor layer 112 illustrated in FIGS. 3G to 3I. In FIG. 3K, the adhesive film (111C) illustrated in FIG. 3J is omitted for ease of viewing, but preferably, an adhesive film (111C) can be formed between the insulating layer 111 and the conductor layer 112 of each of the five sets of insulating layers 111 and conductor layers 112 using a method similar to the method for forming the adhesive film (111C) illustrated in FIG. 3J. The via conductors 113 can be formed in the insulating layers 111. The conductor pads (112p) are provided in the outermost conductor layer 112. As a result, the first build-up part 11 is formed.

Similarly, as illustrated in FIG. 3K, on the second surface (100B) side of the glass plate (100G), four more sets of insulating layers 121 and conductor layers 122 are formed. In FIG. 3K, the adhesive film (121C) illustrated in FIG. 3J is omitted for ease of viewing, but preferably, an adhesive film (121C) can be formed between the insulating layer 121 and the conductor layer 122 of each of the five sets of insulating layers 121 and conductor layers 122 using a method similar to the method for forming the adhesive film (121C) illustrated in FIG. 3J. The via conductors 123 can be formed in the insulating layers 121. The conductor pads (122p) are provided in the outermost conductor layer 122. As a result, the second build-up part 12 is formed.

As described in FIG. 3E, since the adhesive film (100C) is formed on the first surface (100A) and the second surface (100B) of the glass plate (100G), the insulating layer 111 and the insulating layer 121 directly formed on the first surface (100A) and the second surface (100B) firmly adhere to the glass plate (100G). Further, preferably, as described above, the adhesive films (111C, 121C) are formed on the upper surfaces of the insulating layers and the conductor layers constituting the first build-up part 11 and the second build-up part 12, so that the insulating layers and the conductor layers firmly adhere to each other. Therefore, delamination is less likely to occur in the wiring substrate 1.

Next, as illustrated in FIG. 3L, the solder resist layer (SR1) is formed on the first build-up part 11, and the solder resist layer (SR2) is formed on the second build-up part 12. The solder resist layer (SR1) and the solder resist layer (SR2) are each formed, for example, by forming a resin film of a photosensitive epoxy resin or polyimide resin or the like by spraying, lamination, or the like. The openings (SR1o, SR2o) are formed in the solder resist layers (SR1, SR2), for example, by photolithography. On surfaces of the conductor pads (112p) and conductor pads (122p) exposed at the bottom surfaces of the openings (SR1o) and openings (SR2o), a surface protection film (not illustrated) made of Au, Ni/Au, Ni/Pd/Au, solder, or a heat-resistant preflux or the like may formed by electroless plating, solder leveling, spray coating, or the like.

Next, as illustrated in FIG. 3M, the reinforcing material (ST) is positioned on the solder resist layer (SR1). The reinforcing material (ST) is positioned in a region where the conductor pads (112p) are not formed, preferably so as to surround a region where the conductor pads (112p) are formed. As an example, the reinforcing material (ST) is formed separately from the core part 100, the first build-up part 11, and the second build-up part 12. The reinforcing material (ST) is formed, for example, by processing any metal material such as copper alloy, aluminum alloy, iron alloy, or stainless steel into a desired shape by cutting or molding. As an example, high-rigidity stainless steel is used as the reinforcing material (ST). The separately formed reinforcing material (ST) is positioned on the surface of the solder resist layer (SR1) using, for example, a thermosetting resin. Through the above processes, the wiring substrate 1 illustrated in FIG. 1A is completed.

The wiring substrate of the embodiment is not limited to those having the structures illustrated in the drawings and those having the structures, shapes, and materials exemplified in the present specification. The wiring substrate of the embodiment can have any laminated structure and can have any number of conductor layers and insulating layers. For example, FIG. 1A illustrates a structure in which the first build-up part 11 and the second build-up part 12 are respectively formed on the first surface (100A) and the second surface (100B) of the glass plate (100G); however, it is also possible that only one of the build-up parts is formed. Further, it is also possible that the side surfaces (110As) of the metal wiring layer (110A), the side surfaces (110Bs) of the metal wiring layer (110B), and the side surfaces (100Gs) of the glass plate (100G) are not covered by the adhesive film (100C).

The method for manufacturing the wiring substrate of the embodiment is not limited to the method described with reference to the drawings, and the conditions, processing order, and the like thereof may be modified as appropriate. In the method for manufacturing the wiring substrate, depending on the structure of the wiring substrate actually manufactured, some processes may be omitted, or other processes may be added. The method for manufacturing the wiring substrate of the embodiment can manufacture a wiring substrate having any laminated structure and any number of conductor layers and insulating layers. For example, in FIGS. 3A to 3M, the first build-up part 11 and the second build-up part 12 are respectively formed on the first surface (100A) and the second surface (100B) of the glass plate (100G); however, it is also possible that only one of the build-up parts is formed. Further, it is also possible that the adhesive film (100C) is not laminated on the side surfaces (110As) of the metal wiring layer (110A), the side surfaces (110Bs) of the metal wiring layer (110B), and the side surfaces (100Gs) of the glass plate (100G).

Japanese Patent Application Laid-Open Publication No. 2024-29858 describes a wiring substrate that includes an adhesive film for improving adhesion between a substrate and a metal layer. As materials for the adhesive film, silicon nitride or a material mixed with a silane coupling agent is used. In the wiring substrate described in Japanese Patent Application Laid-Open Publication No. 2024-29858, when silane is used for forming the adhesive film, due to considerations for its toxicity, strictly controlled facility environment and work procedures are required, resulting in poor production efficiency. Further, in order to form a high-density film using silicon nitride as a material, high-temperature processing at 300 °C or higher is required by chemical vapor deposition (CVD), which is disadvantageous in terms of work efficiency.

A wiring substrate according to an embodiment of the present invention includes a core part and a build-up part. The core part includes: a glass plate having a first surface and a second surface on an opposite side with respect to the first surface; and a through-hole conductor formed so as to penetrate the glass plate in a thickness direction thereof. The build-up part is formed on the first surface and/or the second surface of the glass plate and includes laminated conductor layers and insulating layers. The build-up part includes four or more conductor layers and four or more insulating layers. The core part includes: a metal wiring layer that is formed on the first surface and/or the second surface of the glass plate and corresponds to a land of the through-hole conductor; and an adhesive film that covers the first surface and/or the second surface of the glass plate exposed from the metal wiring layer and a surface of the metal wiring layer. The adhesive film includes a diamond-like carbon film.

A method for manufacturing a wiring substrate according to an embodiment of the present invention includes: forming, in a glass plate that has a first surface and a second surface on an opposite side with respect to the first surface, a through-hole conductor that penetrates the glass plate in a thickness direction; forming a metal wiring layer on the first surface and/or the second surface of the glass plate; forming an adhesive film that covers the first surface and/or the second surface of the glass plate exposed from the metal wiring layer and a surface of the metal wiring layer; and forming a build-up part by laminating four or more conductor layers and four or more insulating layers on a surface of the adhesive film. The adhesive film includes a diamond-like carbon film.

According to an embodiment of the present invention, a wiring substrate with improved adhesion between a substrate and a metal layer can be formed using a material with low toxicity and without requiring high-temperature processing.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core part comprising a glass plate and a through-hole conductor penetrating through the glass plate; and
a build-up part formed on a surface of the glass plate of the core part and comprising a plurality of conductor layers and a plurality of insulating layers,
wherein the build-up part is formed such that the plurality of conductor layers includes four or more conductor layers and that the plurality of insulating layers includes four or more insulating layers, the core part includes a land and an adhesive film formed such that the land is formed on the surface of the glass plate and positioned on the through-hole conductor and that the adhesive film includes a diamond-like carbon film and is covering a surface of the land and the surface of the glass plate not covered by the land.

2. The wiring substrate according to claim 1, wherein the adhesive film is a laminated film comprising a plurality of films.

3. A wiring substrate, comprising:
a core part comprising a glass plate and a through-hole conductor penetrating through the glass plate;
a build-up part formed on a surface of the glass plate of the core part and comprising a plurality of conductor layers and a plurality of insulating layers; and
an adhesive film comprising a diamond-like carbon film and formed between the build-up part and the glass plate such that the adhesive film is formed in contact with the surface of the glass plate,
wherein the build-up part is formed such that the plurality of conductor layers includes four or more conductor layers and that the plurality of insulating layers includes four or more insulating layers, and the core part is formed such that the through-hole conductor has an end surface formed substantially flush with the surface of the glass plate.

4. The wiring substrate according to claim 3, wherein the adhesive film has an opening that is smaller than the end surface of the through-hole conductor such that the adhesive film is in contact with a portion of the end surface of the through-hole conductor.

5. The wiring substrate according to claim 3, wherein the adhesive film is a laminated film comprising a plurality of films.

6. The wiring substrate according to claim 5, wherein the laminated film of the adhesive film includes a silicon intermediate film formed on the surface of the glass plate, and the diamond-like carbon film laminated on the silicon intermediate film and between the silicon intermediate film and the build-up part.

7. The wiring substrate according to claim 5, wherein the laminated film of the adhesive film includes a first silicon intermediate film, the diamond-like carbon film laminated on the first silicon intermediate film, and a second silicon intermediate film laminated on the diamond-like carbon film.

8. The wiring substrate according to claim 3, wherein the adhesive film is a physical vapor deposition film or a chemical vapor deposition film.

9. The wiring substrate according to claim 3, wherein the adhesive film has a thickness in a range of 10 nm to 10 μm.

10. The wiring substrate according to claim 5, wherein the diamond-like carbon film has a thickness in a range of 10 nm to 10 μm.

11. The wiring substrate according to claim 3, wherein the end surface of the through-hole conductor is a non-roughened surface.

12. A method for manufacturing a wiring substrate, comprising:
forming a through-hole conductor in a glass plate such that the through-hole conductor penetrates through the glass plate;
forming an adhesive film on the glass plate such that the adhesive film covers a surface of the glass plate; and
forming a build-up part on the adhesive film such that the build-up part includes a plurality of conductor layers and a plurality of insulating layers,
wherein the build-up part is formed such that the plurality of conductor layers includes four or more conductor layers and that the plurality of insulating layers includes four or more insulating layers, and the adhesive film includes a diamond-like carbon film.

13. The method for manufacturing a wiring substrate according to claim 12, wherein the forming the adhesive film includes forming the diamond-like carbon film by plasma CVD using a gas containing C₇H₈.

14. The method for manufacturing a wiring substrate according to claim 12, wherein the forming the adhesive film includes forming the adhesive film comprising a laminated film.

15. The method for manufacturing a wiring substrate according to claim 14, wherein the forming the adhesive film includes laminating a silicon intermediate film such that the silicon intermediate film covers the surface of the glass plate, and laminating the diamond-like carbon film on the silicon intermediate film.

16. The method for manufacturing a wiring substrate according to claim 14, wherein the forming the adhesive film includes laminating the diamond-like carbon film such that diamond-like carbon film covers the surface of the glass plate, and laminating a silicon intermediate film on the diamond-like carbon film.

17. The method for manufacturing a wiring substrate according to claim 14, wherein the forming the adhesive film includes laminating a first silicon intermediate film such that the first silicon intermediate film covers the surface of the glass plate, laminating the diamond-like carbon film on the first silicon intermediate film, and laminating a second silicon intermediate film on the diamond-like carbon film.

18. The method for manufacturing a wiring substrate according to claim 12, wherein the adhesive film is formed to have a thickness in a range of 10 nm to 10 μm.

19. The method for manufacturing a wiring substrate according to claim 15, wherein the diamond-like carbon film is formed to have a thickness in a range of 10 nm to 10 μm.

20. The method for manufacturing a wiring substrate according to claim 12, further comprising:
forming a land on the surface of the glass plate such that the land is positioned on the through-hole conductor,
wherein the adhesive film is formed on the land and the glass plate such that the adhesive film covers a surface of the land and the surface of the glass plate not covered by the land, and the surface of the glass plate and the surface of the land are not roughened.
